(19) United States
(12) Patent Application Publication
(10) Pub. No.: US 2025/0048629 A1
(43) Pub. Date: Feb. 6, 2025

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Won Jae CHOI, Icheon-si Gyeonggi-Do (KR); Sung Lae OH, Icheon-si Gyeonggi-do (KR)

(73) Assignee: SK hynix Inc., Icheon-si Gyeonggi-do (KR)

(21) Appl. No.: 18/507,910

(22) Filed: Nov. 13, 2023

(30) Foreign Application Priority Data
Aug. 1, 2023 (KR) 10-2023-0100205

(51) Int. Cl. H10B 43/27; G11C 16/04; H10B 43/10; H10B 43/40

(52) U.S. Cl. CPC H10B 43/27; G11C 16/0483; H10B 43/10; H10B 43/40

(57) ABSTRACT

A semiconductor device may include: a capacitor including a first source electrode, a second source electrode connected in common to a plurality of second access lines, each of the second access lines spaced apart from one another and located on different layers, and a first channel structure located on the first source electrode and penetrating through the plurality of second access lines; and at least one cell string located between a source line and a first access line, the at least one cell string including a second channel structure penetrating through the plurality of second access lines, the plurality of second access lines electrically separated from each other.

### CROSS-REFERENCE TO RELATED APPLICATION

This application claims priority under 35 U.S.C. § 119 (a) to Korean Patent Application No. 10-2023-0100205 filed on Aug. 1, 2023, in the Korean Intellectual Property Office, which is incorporated herein by reference in its entirety.

### BACKGROUND

### 1. Technical Field

Embodiments of the present disclosure generally relate to an integrated circuit, and more particularly, to a semiconductor device and a manufacturing method of the semiconductor device.

### 2. Related Art

Recently, in accordance with the miniaturization, low power consumption, performance improvement, and diversification of electronic devices, semiconductor devices capable of storing information in various electronic devices such as computers and portable communication devices have been demanded.

In order to decrease a size of the semiconductor device and increase data storage capacity of the semiconductor device, the semiconductor device has been developed so that many memory cells may be integrated in the same area by reducing a metal line width on a two-dimensional plane.

However, as the metal line width is reduced on the two-dimensional plane, there is a problem that manufacturing equipment, investment cost, and development period increase exponentially. Accordingly, a method of manufacturing a semiconductor device in a three-dimensional structure has been researched and developed.

### SUMMARY

In an embodiment, a semiconductor device may include: a capacitor including a first source electrode, a second source electrode connected in common to a plurality of second access lines, each of the second access lines spaced apart from one another and located on different layers, and a first channel structure located on the first source electrode and penetrating through the plurality of second access lines; and at least one cell string located between a source line and a first access line, the at least one cell string including a second channel structure penetrating through the plurality of second access lines, the plurality of second access lines electrically separated from each other.

In an embodiment, a manufacturing method of a semiconductor device may include: forming a source line, a first source electrode, and a second source electrode; forming a stack on the source line, the first source electrode, and the second source electrode, the stack including interlayer insulating layers and gate sacrificial layers that are alternately stacked therein; forming a first channel structure on the source line, the first channel structure penetrating through the interlayer insulating layers and the gate sacrificial layers that are alternately stacked; forming a second channel structure on the first source electrode, the second channel structure penetrating through the interlayer insulating layers and the gate sacrificial layers that are alternately stacked; replacing the gate sacrificial layers with gate conductive layers; and electrically separating the gate conductive layers of different layers through which the first channel structure penetrates from each other.

In an embodiment, a semiconductor device may include: a plurality of word lines stacked on top of each other, each word line, from the plurality of word lines, spaced apart from each other; a capacitor including a first channel structure electrically connected to a first source electrode and penetrating through the plurality of word lines, the plurality of word lines connected in common to a second source electrode; and a cell string coupled between a source line and a bit line, the cell string including a second channel structure penetrating through the plurality of word lines.

### BRIEF DESCRIPTION OF THE DRAWINGS

FIGS. 1 and 2 are diagrams for describing a semiconductor device in accordance with an embodiment.

FIG. 3 is a diagram for describing a channel structure of the semiconductor device in accordance with an embodiment.

FIGS. 4 to 10 are diagrams for describing a manufacturing method of a semiconductor device in accordance with an embodiment.

FIG. 11 is a diagram for describing an additional manufacturing method of a semiconductor device in accordance with an embodiment.

FIG. 12 is a diagram for describing a semiconductor device in accordance with another embodiment.

### DETAILED DESCRIPTION

Various embodiments are directed to a semiconductor device capable of having a three-dimensional structure and being more stably operated, and a manufacturing method of the semiconductor device.

In an embodiment, it is possible to increase the stability of signals and power by increasing capacitance of specific nodes or lines inside a semiconductor device.

Hereafter, embodiments in accordance with the technical spirit of the present disclosure will be described with reference to the accompanying drawings.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

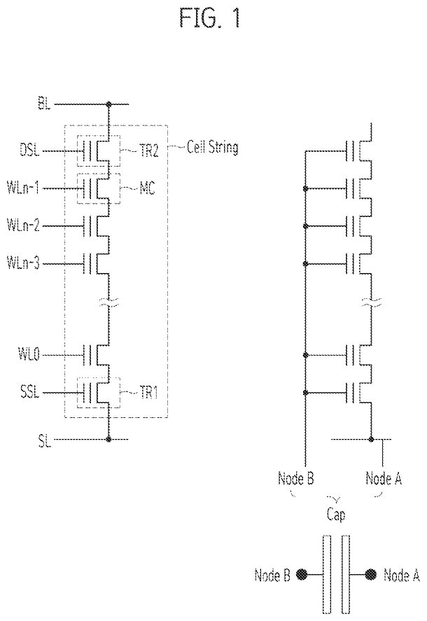

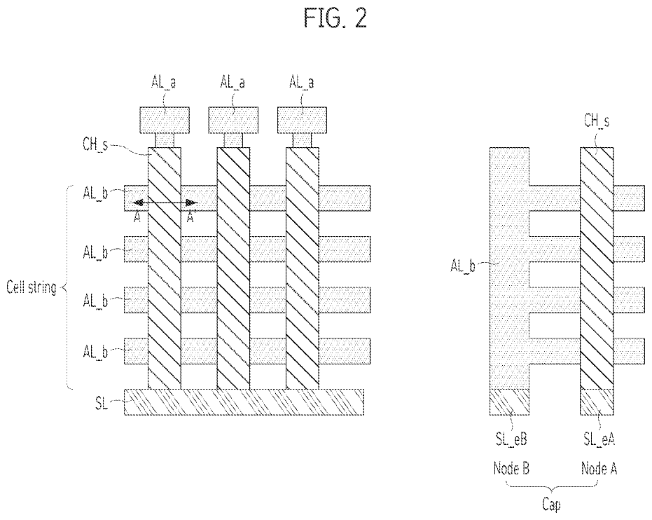

FIGS. 1 and 2 are diagrams for describing a semiconductor device in accordance with an embodiment.

Referring to FIGS. 1 and 2, the semiconductor device in accordance with an embodiment may include at least one cell string Cell string and at least one capacitor Cap.

The cell string Cell string may be electrically connected between a bit line BL and a source line SL. The cell string Cell string may include a first transistor TR1, a plurality of memory cells MC, and a second transistor TR2. The first transistor TR1, the plurality of memory cells MC, and the second transistor TR2 may be connected to each other in series between the source line SL and the bit line BL. A source select line SSL may be input to a gate of the first transistor TR1, a plurality of word lines WL0 to WLn-1 may be input to control gates of the plurality of memory cells MC, and a drain select line DSL may be input to a gate of the second transistor TR2.

The cell string Cell string may include channel structures CH_s formed between first access lines AL_a and the source line SL. In this case, the channel structure CH_s may be formed to penetrate through a plurality of second access lines AL_b. In this case, the first access line AL_a may include the bit line BL, and the plurality of second access lines AL_b may include a plurality of word lines WL.

The capacitor Cap may include a first node Node A and a second node Node B, and may include a dielectric material located between the first node Node A and the second node Node B. In this case, the first node Node A may include a first source electrode SL_eA, and the second node Node B may include a second source electrode SL_eB. The capacitor Cap may be electrically separated from the first access line AL_a. The capacitor Cap may include the second node Node B at which the plurality of second access lines AL_b are connected to the second source electrode SL_eB in common. The capacitor Cap may include a channel structure CH_s formed on the first source electrode SL_eA so as to penetrate through the plurality of second access lines AL_b and electrically connected to the first source electrode SL_eA. The channel structure CH_s of the capacitor Cap may include a dielectric material.

The channel structure CH_s may have a pillar shape in which it extends in a direction perpendicular to an extension direction of the source line SL, and may be a pattern having a high aspect ratio.

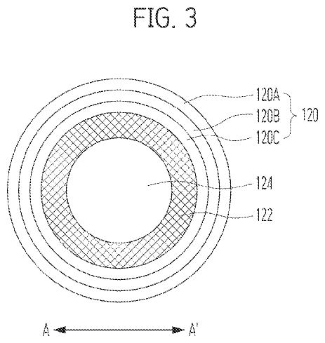

FIG. 3 is a diagram for describing a channel structure of the semiconductor device in accordance with an embodiment. FIG. 3 is a cross-sectional view of the channel structure taken along line A-A′ of FIG. 2. As described above, the channel structure CH_s may have the pillar shape in which it extends in the direction perpendicular to the extension direction of the source line SL.

Referring to FIG. 3, the channel structure CH_s may include a core pillar 124, a channel layer 122, and a memory layer 120.

The core pillar 124 may be formed to extend in the direction perpendicular to the extension direction of the source line SL. The core pillar 124 may include any one insulating layer selected from the group consisting of an oxide layer, a nitride layer, and an oxynitride layer. As an example, the core pillar 124 may include an oxide layer.

The channel layer 122 may be formed to surround the core pillar 124. The channel layer 122 may include a semiconductor layer having a polycrystalline state. As an example, the channel layer 122 may include a polycrystalline silicon layer. The channel layer 122 included in the channel structure CH_s of the cell string Cell string may be electrically connected to the source line SL. Meanwhile, the channel layer 122 included in the channel structure CH_s of the capacitor Cap may be electrically connected to the first source electrode SL_eA.

The memory layer 120 may be formed to surround the channel layer 122. The memory layer 120 may include a blocking layer 120A, a charge trap layer 120B, and a tunnel insulating layer 120C. The tunnel insulating layer 120C may be formed to surround the channel layer 122. The tunnel insulating layer 120C may include an oxide layer. The charge trap layer 120B may be formed to surround the tunnel insulating layer 120C. The charge trap layer 120B may include a nitride layer. The blocking layer 120A may be formed to surround the charge trap layer 120B. The blocking layer 120A may include an oxide layer. In an embodiment of the present disclosure, it has been illustrated that the memory layer 120 has an oxide-nitride-oxide (ONO) structure including the oxide layer, the nitride layer, and the oxide layer, but the present disclosure is not limited thereto.

Referring to FIGS. 2 and 3, the memory layer 120 included in the channel structure CH_s of the cell string Cell string may store charges in the charge trap layer 120B by a voltage level difference between the first access line AL_a corresponding to the bit line BL and the second access line AL_b corresponding to the word line WL.

Meanwhile, the memory layer 120 included in the channel structure CH_s of the capacitor Cap may be formed between the first and second source electrodes SL_eA and SL_eB. Here, the memory layer 120 may have the oxide-nitride-oxide (ONO) structure, and each layer of the oxide-nitride-oxide (ONO) structure between the first and second source electrodes SL_eA and SL_eB may be used as a dielectric material to form a polarization between the first and second source electrodes SL_eA and SL_eB. Accordingly, the semiconductor device in accordance with an embodiment may include the capacitor Cap using the channel structure CH_s having the same structure as the channel structure CH_s of the cell string Cell string.

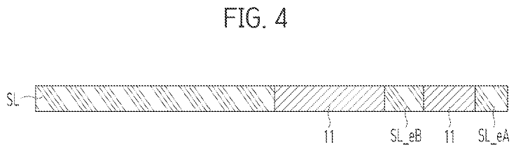

FIGS. 4 to 10 are diagrams for describing a manufacturing method of a semiconductor device in accordance with an embodiment.

Referring to FIG. 4, a source line SL, a first source electrode SL_eA, and a second source electrode SL_eB may be formed by patterning a source layer (not illustrated). The source layer may include a doped semiconductor layer. For example, the source layer may include an n-type doped silicon layer. Here, an insulating layer 11 may be formed between the source line SL and the second source electrode SL_eB and between the second source electrode SL_eB and the first source electrode SL_eA. Accordingly, the source line SL, the second source electrode SL_eB, and the first source electrode SL_eA may be electrically separated from each other.

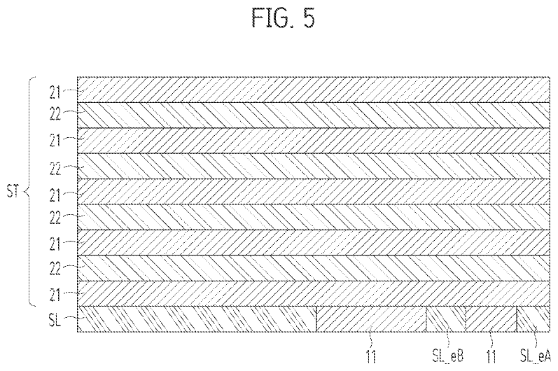

Referring to FIG. 5, a stack ST may be formed. A stack ST in which interlayer insulating layers 21 and gate sacrificial layers 22 are alternately stacked may be formed on the source line SL, the second source electrode SL_eB, and the first source electrode SL_eA. The gate sacrificial layer 22 may be made of a material having an etching selectivity with respect to the interlayer insulating layer 21. Each of the interlayer insulating layer 21 and the gate sacrificial layer 22 may include any one selected from the group consisting of an oxide layer, a nitride layer, and an oxynitride layer. As an example, the interlayer insulating layer 21 may include an oxide layer, and the gate sacrificial layer 22 may include a nitride layer.

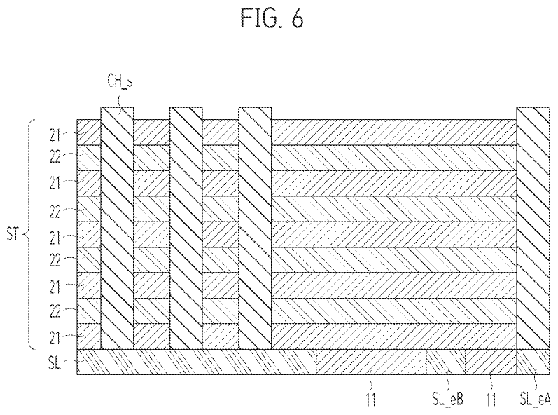

Referring to FIG. 6, channel structures CH_s may be formed. The channel structures CH_s may be formed on the source line SL and the first source electrode SL_eA. For example, channel holes (not illustrated) penetrating through the interlayer insulating layers 21 and the gate sacrificial layers 22 may be formed by forming a mask pattern on the stack ST and then etching the stack ST using the mask pattern as an etching barrier. Thereafter, a memory layer 120 may be formed along a surface of the channel hole. The memory layer 120 may be formed as a stacked layer in which a blocking layer 120A, a charge trap layer 120B, and a tunnel insulating layer 120C are sequentially stacked. For example, the blocking layer 120A and the tunnel insulating layer 120C may be formed as oxide layers, and the charge trap layer 120B may be formed as a nitride layer. Next, a semiconductor layer (not illustrated) may be formed on the memory layer 120. The semiconductor layer may be formed as a polycrystalline silicon layer. A channel layer 122 may be formed by etching the semiconductor layer. A core pillar 124 (see FIG. 3) gap-filling an etched space may be formed on the channel layer 122. The core pillar 124 may include any one insulating layer selected from the group consisting of an oxide layer, a nitride layer, and an oxynitride layer. As an example, the core pillar 124 may include an oxide layer.

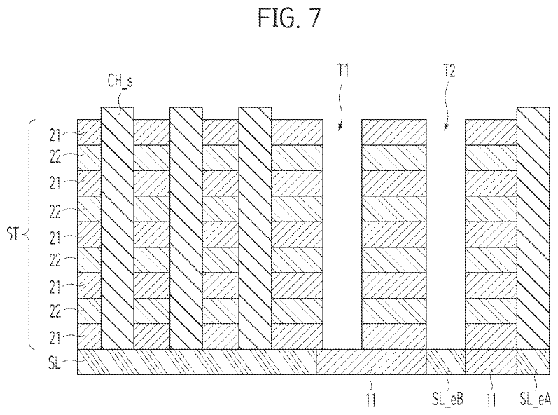

Referring to FIG. 7, a first trench T1 and a second trench T2 may be formed. The first trench T1 may be formed by etching the stack ST on the insulating layer 11 between the source line SL and the second source electrode SL_eB. The second trench T2 may be formed by etching the stack ST on the second source electrode SL_eB. Meanwhile, according to another embodiment of the present disclosure, a hole (not illustrated) may be formed by etching the stack ST on the second source electrode SL_eB.

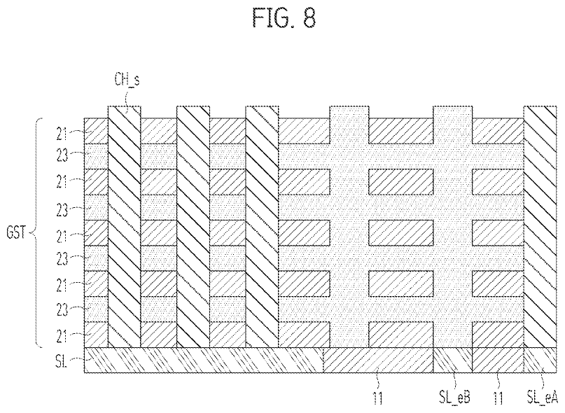

Referring to FIG. 8, gate conductive layers 23 may be formed. For example, the gate sacrificial layers 22 may be removed through the first and second trenches T1 and T2. Next, spaces in which the gate sacrificial layers 22 are removed and in the first and second trenches T1 and T2 may be gap-filled with the gate conductive layers 23. The gate conductive layer 23 may include a conductive layer containing metal. As an example, the gate conductive layer 23 may be formed as a tungsten layer. As another example, the gate conductive layer 23 may be formed as a stacked layer in which a titanium nitride layer and a tungsten layer are stacked. Thus, a gate stack GST in which the interlayer insulating layers 21 and the gate conductive layers 23 are alternately stacked may be formed.

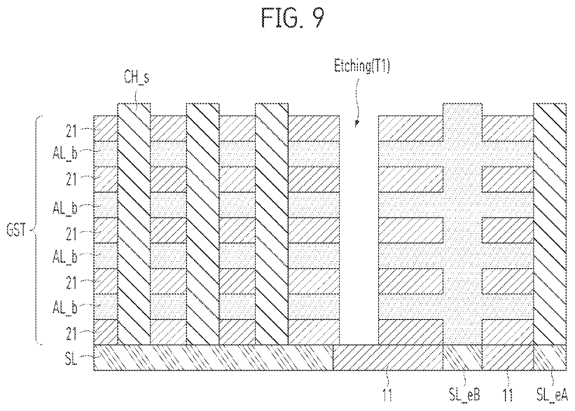

Referring to FIG. 9, a plurality of second access lines AL_b may be formed. For example, the gate conductive layers 23 may be separated from each other by etching the gate conductive layer 23 gap-filled in the first trench T1. The gate conductive layers 23 located between the interlayer insulating layers 21 and separated from each other by an etching process may be used as the plurality of second access lines AL_b. Meanwhile, the gate conductive layer 23 gap-filled in the second trench T2 may be electrically connected in common to the gate conductive layers 23 between the interlayer insulating layers 21, and be electrically connected to the second source electrode SL_eB.

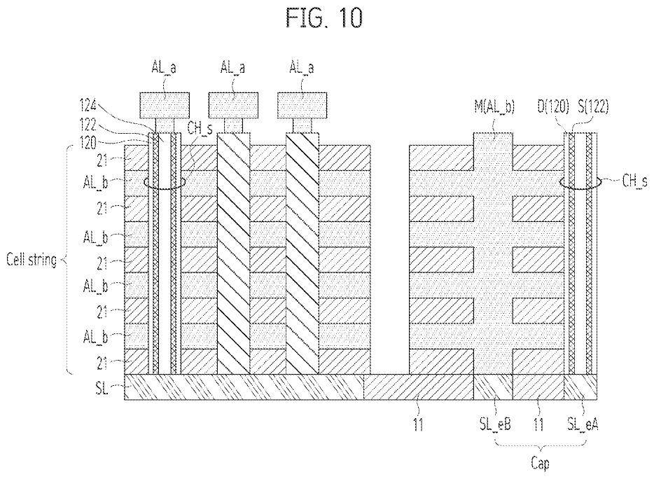

Referring to FIG. 10, first access lines AL_a may be formed. For example, the first access lines AL_a may be formed on the channel structures CH_s formed on the source line SL and formed to penetrate through the plurality of second access lines AL_b f electrically separated from each other and the interlayer insulating layers 21. The channel structure CH_s and the first access line AL_a may be electrically connected to each other. The channel structure CH_s may include the memory layer 120, the channel layer 122, and the core pillar 124, as described above. Here, the first access line AL_a may include a bit line, and the plurality of second access lines AL_b may include a plurality of word lines. The channel structure CH_s electrically connected to the first access line AL_a may store charges in the charge trap layer 120b of the memory layer 120 by a voltage difference between the first access line AL_a and the second access line AL_b. Accordingly, the channel structure CH_s electrically connected to the first access line AL_a may include a memory cell MC.

Meanwhile, the channel structure CH_s which is electrically separated from the first access lines AL_a, to which the second access lines AL_b of different layers are connected in common, and which is formed on the first source electrode SL_eA may be included in a capacitor Cap forming a polarization between the plurality of second access lines AL_b connected in common and the channel layer 122. Here, the second access lines AL_b connected in common may be electrically connected to the second source electrode SL_eB, and the channel layer 122 may be electrically connected to the first source electrode SL_eA. In detail, the capacitor Cap may use the channel layer 122 of the channel structure CH_s as a semiconductor layer S, may use the second access lines AL_b connected in common as a conductive layer M, and may use the memory layer 120 having the ONO structure in the channel structure CH_s as a dielectric material D.

As a result, the capacitor Cap of the semiconductor device in accordance with an embodiment may be formed in an M-ONO-S structure.

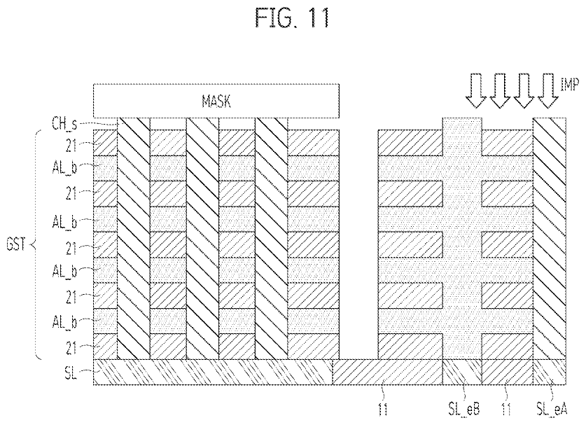

FIG. 11 is a diagram for describing an additional manufacturing method of a semiconductor device in accordance with an embodiment. FIG. 11 is a diagram for describing a manufacturing method for improving electrical characteristics of the channel layer 122 constituting the capacitor Cap. FIG. 11 may be a diagram for describing a manufacturing method that may be added after the manufacturing method described in FIG. 9 and before the manufacturing method of FIG. 10.

Referring to FIG. 11, the channel layer of the channel structure CH_s formed on the first source electrode SL_eA may be made to be conductive. For example, a mask MASK may be formed to cover the channel structures CH_s formed on the source line SL. Thereafter, the channel layer of the channel structure CH_s formed on the first source electrode SL_eA may be made to be conductive by performing an ion implant process (IMP) on the channel structure CH_S formed on the first source electrode SL_eA and performing a heat treatment process. Accordingly, in an embodiment, the channel layer of the channel structure CH_s formed on the first source electrode SL_eA may have electrical characteristics better than those of the channel layer of the channel structure CH_s formed on the source line SL. As a result, in an embodiment, characteristics of the capacitor using the channel layer of the channel structure CH_s made to be conductive by being subjected to the ion implantation process and the heat treatment process may be better than those of the capacitor using the channel layer of the channel structure that is not subjected to the ion implantation process and the heat treatment process.

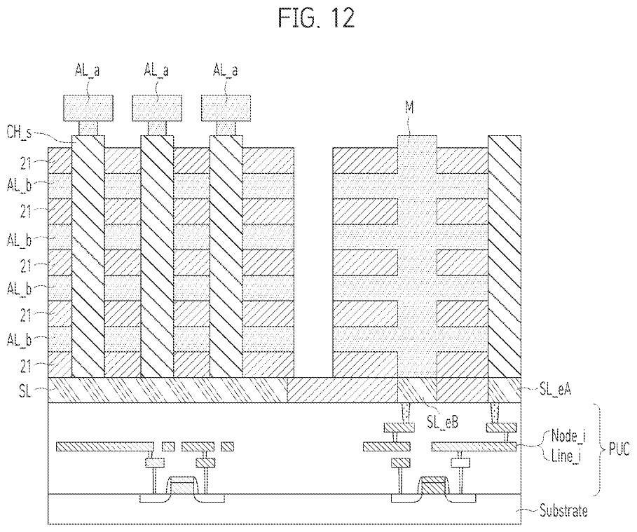

FIG. 12 is a diagram for describing a semiconductor device in accordance with another embodiment.

The manufacturing method of a semiconductor device described in FIGS. 4 to 10 or FIGS. 4 to 11 may include a manufacturing method after a circuit (e.g., a peripheral circuit) is formed on a substrate Substrate, that is, a manufacturing method of a peri under cell (PUC) structure. In addition, at least one of the first and second source electrodes SL_eA and SL_eB may be connected to a specific node Node_i or a specific line Line_i inside the peripheral circuit.

Accordingly, in the semiconductor device in accordance with another embodiment, it is possible to increase capacitance of a specific node Node_i or a specific line Line_i requiring stability of a signal or power by connecting at least one of the first and second source electrodes SL_eA and SL_eB to the specific node Node_i or the specific line Line_i.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a capacitor including a first source electrode, a second source electrode connected in common to a plurality of second access lines, each of the second access lines spaced apart from one another and located on different layers, and a first channel structure located on the first source electrode and penetrating through the plurality of second access lines; and
at least one cell string located between a source line and a first access line, the at least one cell string including a second channel structure penetrating through the plurality of second access lines, the plurality of second access lines electrically separated from each other.

2. The semiconductor device of claim 1, wherein each of the first and second channel structures comprises:
a core pillar extending in a direction substantially perpendicular to an extension direction of the source line;
a channel layer formed to surround the core pillar, and
a memory layer formed to surround the channel layer.

3. The semiconductor device of claim 1, wherein the memory layer comprises:
a tunnel insulating layer formed to surround the channel layer;
a charge trap layer formed to surround the tunnel insulating layer, and
a blocking layer formed to surround the charge trap layer.

4. The semiconductor device of claim 3, wherein the tunnel insulating layer and the blocking layer each include an oxide layer, and the charge trap layer includes a nitride layer.

5. The semiconductor device of claim 4, wherein the capacitor forms a polarization between the first source electrode and the second source electrode using the memory layer having an oxide-nitride-oxide structure as a dielectric material.

6. The semiconductor device of claim 1, further comprising a peripheral circuit including a specific node or a specific line connected to at least one of the first source electrode and the second source electrode.

7. The semiconductor device of claim 6, wherein the peripheral circuit is formed below the source line, the first source electrode, and the second source electrode.

8. A manufacturing method of a semiconductor device, the manufacturing method comprising:
forming a source line, a first source electrode, and a second source electrode;
forming a stack on the source line, the first source electrode, and the second source electrode, the stack including interlayer insulating layers and gate sacrificial layers that are alternately stacked therein;
forming a first channel structure on the source line, the first channel structure penetrating through the interlayer insulating layers and the gate sacrificial layers that are alternately stacked;
forming a second channel structure on the first source electrode, the second channel structure penetrating through the interlayer insulating layers and the gate sacrificial layers that are alternately stacked;
replacing the gate sacrificial layers with gate conductive layers; and
electrically separating the gate conductive layers of different layers through which the first channel structure penetrates from each other.

9. The manufacturing method of claim 8, wherein the replacing of the gate sacrificial layers with the gate conductive layers comprises:
forming a first trench and a second trench between the first channel structure and the second channel structure, the first trench and the second trench penetrating through the interlayer insulating layers and the gate sacrificial layers;
removing the gate sacrificial layers through the first and second trenches; and
gap-filling spaces in which the gate sacrificial layers are removed and the first and second trenches with the gate conductive layers.

10. The manufacturing method of claim 9,
wherein the first trench is formed between the first channel structure and the second source electrode, and
wherein the second trench is formed on the second source electrode.

11. The manufacturing method of claim 10, wherein the electrical separating of the gate conductive layers of the different layers through which the first channel structure penetrates from each other includes etching and removing the gate conductive layer gap-filled in the first trench.

12. The manufacturing method of claim 11, wherein each of the first and second channel structures includes a core pillar, a channel layer, and a memory layer.

13. The manufacturing method of claim 12, wherein the core pillar is formed to extend in a direction substantially perpendicular to an extension direction of the source line,
the channel layer is formed to surround the core pillar, and
the memory layer is formed to surround the channel layer.

14. The manufacturing method of claim 13, wherein the memory layer has an oxide-nitride-oxide structure.

15. The manufacturing method of claim 14, wherein the memory layer of the second channel structure forms a polarization between the first source electrode and the second source electrode.

16. A semiconductor device comprising:
a plurality of word lines stacked on top of each other, each word line, from the plurality of word lines, spaced apart from each other;
a capacitor including a first channel structure electrically connected to a first source electrode and penetrating through the plurality of word lines, the plurality of word lines connected in common to a second source electrode; and
a cell string coupled between a source line and a bit line, the cell string including a second channel structure penetrating through the plurality of word lines.
